(19) United States
(12) Patent Application Publication
(10) Pub. No.: US 2026/0026335 A1
(43) Pub. Date: Jan. 22, 2026

(54) INTEGRATED CIRCUIT AND METHOD FOR FABRICATING THE SAME

(71) Applicant: Samsung Electronics Co., Ltd., Suwon-si (KR)

(72) Inventors: Min Sung KANG, Suwon-si (KR); Hyoung Yol MUN, Suwon-si (KR); Woo Sun YANG, Suwon-si (KR)

(73) Assignee: Samsung Electronics Co., Ltd., Suwon-si (KR)

(21) Appl. No.: 19/068,359

(22) Filed: Mar. 3, 2025

(30) Foreign Application Priority Data
Jul. 16, 2024 (KR) 10-2024-0093533

(51) Int. Cl. H01L 23/528; H01L 21/768; H01L 23/522; H01L 23/532

(52) U.S. Cl. CPC H01L 23/528; H01L 21/76816; H01L 21/7682; H01L 21/76832; H01L 23/5226; H01L 23/5283; H01L 23/53295

(57) ABSTRACT

According to some example embodiments, an integrated circuit includes a first inter-wiring insulating film on a substrate, a first and second wiring patterns spaced apart from each other on the first inter-wiring insulating film, a first etch stop layer on the first inter-wiring insulating film, the first and second wiring patterns, and a second inter-wiring insulating film on the first etch stop layer. Each of the first and second wiring patterns includes a first lower pattern in the first inter-wiring insulating film, and a first upper pattern on an upper surface of the first inter-wiring insulating film. The first etch stop layer extends along profiles of the upper surface of the first inter-wiring insulating film, and a side face and an upper surface of the first upper pattern. The second inter-wiring insulating film defines a first void between the first wiring pattern and the second wiring pattern.

### CROSS-REFERENCE TO RELATED APPLICATION

This U.S. non-provisional application claims priority under 35 U.S.C. § 119 to Korean Patent Application No. 10-2024-0093533 filed on Jul. 16, 2024, in the Korean Intellectual Property Office, the entire contents of which are herein incorporated by reference.

### BACKGROUND

Some example embodiments relate to an integrated circuit and a method for fabricating the same.

As integrated circuits are miniaturized, wiring structures included in the integrated circuit are also miniaturized. It is beneficial to improve the performance and reliability of the integrated circuit by reducing damage to the wiring structure, and limiting an increase in resistance and leakage current of the wiring structure.

### SUMMARY

Some example embodiments are directed to integrated circuits having improved performance and reliability.

Some example embodiments are directed to methods for fabricating an integrated circuit having improved performance and reliability.

According to some example embodiments, an integrated circuit includes a substrate, a first inter-wiring insulating film on the substrate, a first wiring pattern and a second wiring pattern spaced apart from each other on the first inter-wiring insulating film, a first etch stop layer on the first inter-wiring insulating film, the first wiring pattern, and the second wiring pattern, and a second inter-wiring insulating film on the first etch stop layer, wherein each of the first wiring pattern and the second wiring pattern includes a first lower pattern in the first inter-wiring insulating film, and a first upper pattern on an upper surface of the first inter-wiring insulating film, the first etch stop layer extends along profiles of the upper surface of the first inter-wiring insulating film, and a side face and an upper surface of the first upper pattern, and the second inter-wiring insulating film defines a first void between the first upper pattern of the first wiring pattern and the first upper pattern of the second wiring pattern.

According to some example embodiments, an integrated circuit includes a substrate, a first inter-wiring insulating film on the substrate, a wiring pattern including a lower pattern in the first inter-wiring insulating film, and an upper pattern on an upper surface of the first inter-wiring insulating film, an etch stop layer on the first inter-wiring insulating film and the upper pattern, and a second inter-wiring insulating film on the etch stop layer, wherein at an interface between the lower pattern and the upper pattern, a first width of the lower pattern is less than a second width of the upper pattern, the etch stop layer extends along profiles of the upper surface of the first inter-wiring insulating film, and a side face and an upper surface of the upper pattern, and the second inter-wiring insulating film fills at least a portion of a region on the side face of the upper pattern.

According to some example embodiments, an integrated circuit includes a substrate, a lower inter-wiring insulating film on the substrate, a lower wiring pattern on the lower inter-wiring insulating film, a first etch stop layer which extends along an upper surface of the lower inter-wiring insulating film and an upper surface of the lower wiring pattern, a first inter-wiring insulating film on the first etch stop layer, a wiring pattern including a lower pattern having a first width in the first inter-wiring insulating film, and an upper pattern having a second width greater than the first width on an upper surface of the first inter-wiring insulating film, a via pattern penetrating the first inter-wiring insulating film and the first etch stop layer and connecting the lower pattern and the lower wiring pattern, a second etch stop layer extending along profiles of an upper surface of the first inter-wiring insulating film, and a side face and an upper surface of the upper pattern, and a second inter-wiring insulating film on the second etch stop layer, wherein the second inter-wiring insulating film defines a void on the side face of the upper pattern.

### BRIEF DESCRIPTION OF THE DRAWINGS

The above and other aspects and features of the present disclosure will become more apparent by describing in detail some example embodiments thereof with reference to the attached drawings, in which:

FIG. 1 is a schematic cross-sectional view of an integrated circuit, according to some example embodiments.

FIGS. 2, 3, and 4 are enlarged views of a region R1 of FIG. 1.

FIG. 5 is a schematic cross-sectional view of an integrated circuit, according to some example embodiments.

FIG. 6 is an enlarged view of a region R2 of FIG. 5.

FIGS. 7, 8, and 9 are schematic cross-sectional views of an integrated circuit, according to some example embodiments.

FIGS. 10, 11, 12, 13, 14, 15, 16, 17, 18, 19, 20, 21, 22, and 23 illustrate operations in a method for fabricating an integrated circuit, according to some example embodiments.

FIG. 24 illustrates an operation in the method for fabricating the integrated circuit, according to some example embodiments.

### DETAILED DESCRIPTION

It will be understood that when an element such as a layer, film, region, or substrate is referred to as being “on” another element, it may be directly on the other element or intervening elements may also be present. In contrast, when an element is referred to as being “directly on” another element, there are no intervening elements present. It will further be understood that when an element is referred to as being “on” another element, it may be above or beneath or adjacent (e.g., horizontally adjacent) to the other element.

Hereinafter, the terms “lower portion” and “upper portion” are for convenience of description and do not limit the positional relationship.

As used herein, the term “and/or” includes any and all combinations of one or more of the associated listed items. Expressions such as “at least one of,” when preceding a list of elements, modify the entire list of elements and do not modify the individual elements of the list. For example, “at least one of A, B, and C,” and similar language (e.g., “at least one selected from the group consisting of A, B, and C,” “at least one of A, B, or C”) may be construed as A only, B only, C only, or any combination of two or more of A, B, and C, such as, for instance, ABC, AB, BC, and AC.

It will be understood that elements and/or properties thereof may be recited herein as being “the same” or “equal” as other elements, and it will be further understood that elements and/or properties thereof recited herein as being “identical” to, “the same” as, or “equal” to other elements may be “identical” to, “the same” as, or “equal” to or “substantially identical” to, “substantially the same” as or “substantially equal” to the other elements and/or properties thereof. Elements and/or properties thereof that are “substantially identical” to, “substantially the same” as or “substantially equal” to other elements and/or properties thereof will be understood to include elements and/or properties thereof that are identical to, the same as, or equal to the other elements and/or properties thereof within manufacturing tolerances and/or material tolerances. Elements and/or properties thereof that are identical or substantially identical to and/or the same or substantially the same as other elements and/or properties thereof may be structurally the same or substantially the same, functionally the same or substantially the same, and/or compositionally the same or substantially the same. While the term “same,” “equal” or “identical” may be used in description of some example embodiments, it should be understood that some imprecisions may exist. Thus, when one element, value, and/or property is referred to as being the same as another element, value, and/or property, it should be understood that an element, value, and/or property is the same as another element, value, and/or property within a desired manufacturing or operational tolerance range (e.g., ±10%).

It will be understood that elements and/or properties thereof described herein as being “substantially” the same and/or identical encompasses elements and/or properties thereof that have a relative difference in magnitude that is equal to or less than 10%. Further, regardless of whether elements and/or properties thereof are modified as “substantially,” it will be understood that these elements and/or properties thereof should be construed as including a manufacturing or operational tolerance (e.g., ±10%) around the stated elements and/or properties thereof.

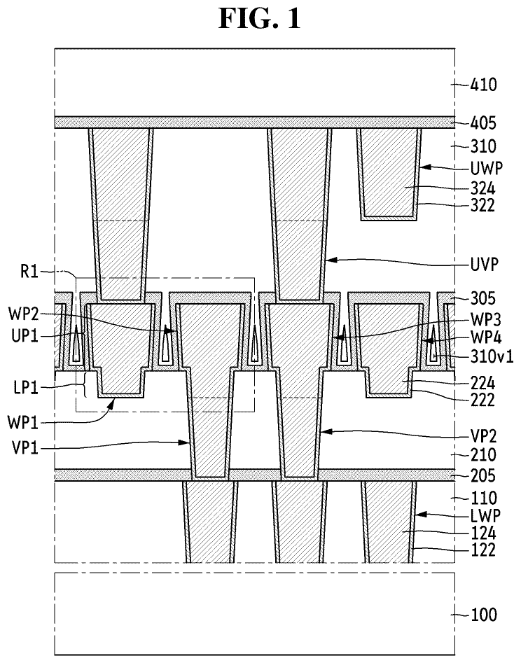

Hereinafter, some example embodiments of integrated circuits will be discussed referring to FIGS. 1 to 9.

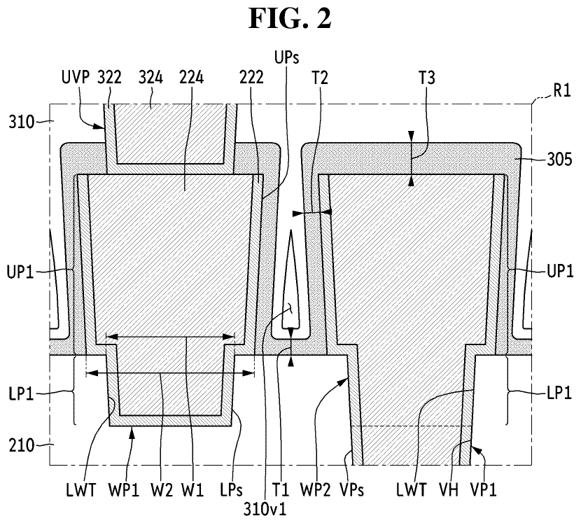

FIG. 1 is a schematic cross-sectional view of an integrated circuit, according to some example embodiments. FIGS. 2 to 4 are enlarged views of a region R1 of FIG. 1.

Referring to FIGS. 1 to 4, the integrated circuit, according to some example embodiments, may include a substrate 100, a lower inter-wiring insulating film 110, lower wiring patterns LWP, a first etch stop layer 205, a first inter-wiring insulating film 210, first to fourth wiring patterns WP1 to WP4, first and second via patterns VP1 and VP2, a second etch stop layer 305, a second inter-wiring insulating film 310, upper wiring patterns UWP, upper via patterns UVP, a third etch stop layer 405, and an upper inter-wiring insulating film 410.

The substrate 100 may be bulk silicon or silicon-on-insulator (SOI). The substrate 100 may be a silicon substrate, or may include other materials, for example, silicon germanium, gallium arsenide, SGOI (silicon germanium on insulator), indium antimonide, lead telluride, indium arsenide, indium phosphide, gallium arsenide or gallium antimonide. Alternatively, the substrate 100 may be one in which an epitaxial layer is formed on a base substrate, and may be a ceramic substrate, a quartz substrate, a display glass substrate, or the like.

A semiconductor device including the integrated circuit may be formed on the substrate 100. The semiconductor device formed on the substrate 100 may include, in some example embodiments, at least one of volatile memory devices such as a DRAM (dynamic random access memory) or a SRAM (static random access memory); non-volatile memory devices such as a NAND flash (NAND flash), a PRAM (Phase-change Random Access Memory), a MRAM (Magnetoresistive Random Access Memory), a FeRAM (Ferroelectric Random Access Memory) or a RRAM (Resistive Random Access Memory); logic elements such as a CPU (central processing unit), a GPU (graphic processing unit), a controller, an ASIC (application specific integrated circuit), and an AP (application processor); combinations thereof and the like.

The lower inter-wiring insulating film 110 may be formed on the substrate 100. The lower inter-wiring insulating film 110 may include, in some example embodiments, at least one of silicon oxide, silicon nitride, silicon oxynitride, silicon oxycarbide, silicon boron nitride, silicon boron carbonitride, silicon oxycarbonitride, a low dielectric constant material having a lower dielectric constant than silicon oxide, an ultra-low dielectric constant material having a dielectric constant of less than 2.5 (or about 2.5), a high dielectric constant material having a dielectric constant larger than silicon oxide, and/or a combination thereof.

The low dielectric constant material may include, for example, at least one of FOX (Flowable Oxide), TOSZ (Torene SilaZene), USG (Undoped Silica Glass), BSG (Borosilica Glass), PSG (PhosphoSilica Glass), BPSG (BoroPhosphoSilica Glass), PETEOS (Plasma Enhanced Tetra Ethyl Ortho Silicate), FSG (Fluoride Silicate Glass), CDO (Carbon Doped silicon Oxide), Xerogel, Aerogel, Amorphous Fluorinated Carbon, OSG (Organo Silicate Glass), Parylene, BCB (bis-benzocyclobutenes), SiLK, polyimide, porous polymeric material, and combinations thereof.

The high dielectric constant material may include, in some example embodiments, at least one of hafnium oxide, hafnium silicon oxide, hafnium aluminum oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, lead zinc niobate, and combinations thereof.

The lower wiring patterns LWP may be formed in the lower inter-wiring insulating film 110 and may be spaced apart from each other. For example, the lower wiring patterns LWP may be formed in (e.g., within trenches) the lower inter-wiring insulating film 110. The lower wiring patterns LWP may be electrically insulated from each other by the lower inter-wiring insulating film 110.

Each lower wiring pattern LWP may include a first barrier conductive film 122 and a first filling conductive film 124 that are stacked or otherwise formed in order. The first barrier conductive film 122 may include a metal or a metal nitride for reducing, limiting, or minimizing diffusion of the first filling conductive film 124. For example, the first barrier conductive film 122 may include, in some example embodiments, at least one of titanium (Ti), tantalum (Ta), tungsten (W), nickel (Ni), cobalt (Co), platinum (Pt), alloys thereof or nitrides thereof. In some example embodiments, the first barrier conductive film 122 may include at least one of a titanium film (Ti film), a tantalum film (Ta film), a titanium nitride film (TiN film) or a tantalum nitride film (TaN). The first filling conductive film 124 may fill or be formed in a region or volume of the lower wiring pattern LWP that remains after the first barrier conductive film 122 is formed or that is otherwise defined by the first barrier conductive film 122. For example, the first filling conductive film 124 may include, in some example embodiments, at least one of aluminum (Al), copper (Cu), tungsten (W), molybdenum (Mo), cobalt (Co), ruthenium (Ru) or alloys thereof. In some example embodiments, the first filling conductive film 124 may include copper (Cu).

The first etch stop layer 205 may be formed on the lower inter-wiring insulating film 110 and the lower wiring pattern LWP. For example, the first etch stop layer 205 may conformally extend along the upper face of the lower inter-wiring insulating film 110 and the upper faces of the lower wiring patterns LWP.

The first etch stop layer 205 may be provided as an etch stop layer in an etching process for forming the first and second via patterns VP1 and VP2. The first etch stop layer 205 may include, in some example embodiments, at least one of silicon nitride (SiN), silicon oxynitride (SiON), silicon oxycarbonitride (SiOCN), silicon boronitride (SiBN), silicon oxyboronitride (SiOBN), silicon oxycarbide (SiOC), silicon carbonitride (SiCN), aluminum nitride (AlN), aluminum oxide (AIO) or a combination thereof.

The first inter-wiring insulating film 210 may be formed on the first etch stop layer 205. The first inter-wiring insulating film 210 may cover the upper face of the first etch stop layer 205. The first inter-wiring insulating film 210 may include, in some example embodiments, at least one of silicon oxide, silicon nitride, silicon oxynitride, silicon oxycarbide, silicon boron nitride, silicon boron carbonitride, silicon oxycarbonitride, the low dielectric constant material, the ultra-low dielectric constant material, the high dielectric constant material and/or a combination thereof.

The first to fourth wiring patterns WP1 to WP4 may be formed on the first inter-wiring insulating film 210 and may be spaced apart from each other. The first to fourth wiring patterns WP1 to WP4 may each extend in a same direction (e.g., a first vertical direction).

Each of the first to fourth wiring patterns WP1 to WP4 may include a first lower pattern LP1 and a first upper pattern UP1 that may be defined based on the upper surface of the first inter-wiring insulating film 210. The first lower pattern LP1 may be located inside or within the first inter-wiring insulating film 210, and the first upper pattern UP1 may be located on the upper surface of the first inter-wiring insulating film 210. For example, as shown in FIG. 2, the first inter-wiring insulating film 210 may include a first wiring trench LWT formed (or extending) from the upper surface of the first inter-wiring insulating film 210. The first wiring trench LWT may extend in one direction (e.g., a first vertical direction). The first lower pattern LP1 may be formed inside the first wiring trench LWT. The first upper pattern UP1 may be formed on the upper surface of the first inter-wiring insulating film 210 and connected to the upper part of the first lower pattern LP1.

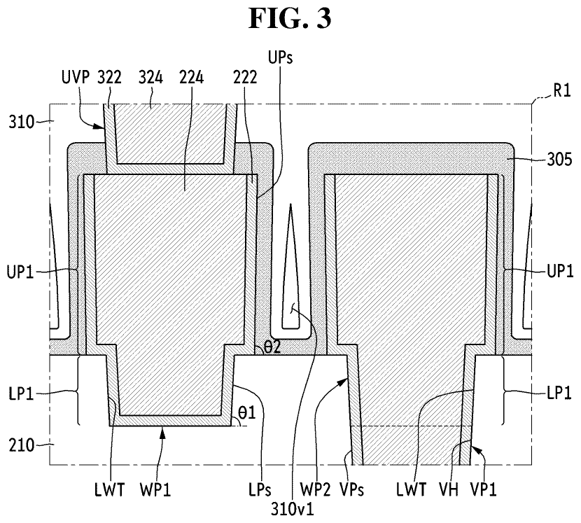

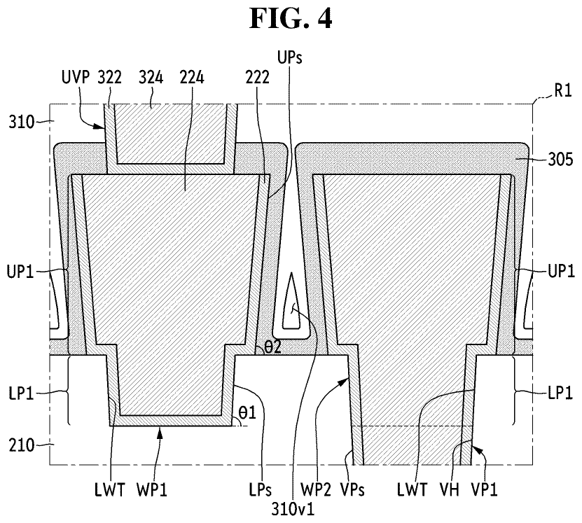

Although an inclination or slope or tilt of a side face LPs of the first lower pattern LP1 and an inclination or slope or tilt of a side face UPs of the first upper pattern UP1 are shown as being same as each other in FIG. 2, this is merely an example. In some example embodiments, the inclination or slope or tilt of the side face LPs of the first lower pattern LP1 and the inclination or slope or tilt of the side face UPs of the first upper pattern UP1 may be different from each other. In some example embodiments, and as shown in FIG. 3, a first external angle θ1 formed by the side face LPs of the first lower pattern LP1 may be smaller than a second external angle θ2 formed by the side face UPs of the first upper pattern UP1 with respect to a horizontal plane parallel to the upper face of the substrate 100. In some example embodiments, and as shown in FIG. 4, the first external angle θ1 formed by the side face LPs of the first lower pattern LP1 may be greater than the second external angle θ2 formed by the side face Ups of the first upper pattern UP1 with respect to the horizontal plane parallel to the upper face of the substrate 100.

In some example embodiments, the width of the first lower pattern LP1 may decrease toward (e.g., in the direction of) the first etch stop layer 205. For example, the first external angle θ1 may be an acute angle. This may be due to the characteristics of the etching process for forming the first lower pattern LP1. In some example embodiments, the width of the first upper pattern UP1 may decrease toward (e.g., in the direction of) the first lower pattern LP1. This may be due to the characteristics of the etching process for forming the first upper pattern UP1. For example, the second external angle θ2 may be an acute angle. Here, the width refers to a dimension in a direction intersecting the direction in which the first to fourth wiring patterns WP1 to WP4 extend (for example, a second horizontal direction intersecting the first vertical direction).

In some example embodiments, the side face UPs of the first upper pattern UP1 may protrude or extend beyond the side face LPs of the first lower pattern LP1. The side face LPs of the first lower pattern LP1 and the side face UPs of the first upper pattern UP1 may not be continuous or collinear. For example, as shown in FIG. 2, at an interface between the first lower pattern LP1 and the first upper pattern UP1 (e.g., interface defined by the upper surface of the first inter-wiring insulating film 210), the first width W1 of the first lower pattern LP1 may be smaller than the second width W2 of the first upper pattern UP1. A part of the lower face of the first upper pattern UP1 may come into contact with the upper surface of the first inter-wiring insulating film 210.

The first and second via patterns VP1 and VP2 may be formed between the lower wiring patterns LWP and the first to fourth wiring patterns WP1 to WP4. Each of the first and second via patterns VP1 and VP2 may extend from the lower surface of the first lower pattern LP1 in a vertical direction intersecting the upper face of the substrate 100. For example, as shown in FIG. 2, a via hole VH may be formed extending from the lower surface of the first lower pattern LP1. The via hole VH may extend in the vertical direction and penetrate the first inter-wiring insulating film 210 and the first etch stop layer 205. The first via pattern VP1 may be formed inside the via hole VH.

The first and second via patterns VP1 and VP2 may electrically connect the lower wiring patterns LWP to any of the first to fourth wiring patterns WP1, WP3. For example, and as illustrated, the first via pattern VP1 may penetrate the first inter-wiring insulating film 210 and the first etch stop layer 205 to connect one of the lower wiring patterns LWP to the first lower pattern LP1 of the second wiring pattern WP2. Also, for example, the second via pattern VP2 may penetrate the first inter-wiring insulating film 210 and the first etch stop layer 205 to connect the other of the lower wiring patterns LWP to the first lower pattern LP1 of the third wiring pattern WP3.

In some example embodiments, a side face VPs of each of the first and second via patterns VP1 and VP2 may be continuous or collinear with the side face LPs of the first lower pattern LP1. For example, the side face VPs of each of the first and second via patterns VP1 and VP2 may be smoothly or uninterruptedly connected to the side face LPs of the first lower pattern LP1. For example, as shown in FIG. 2, at the interface between the first lower pattern LP1 of the second wiring pattern WP2 and the first via pattern VP1, the width of the first lower pattern LP1 and the width of the first via pattern VP1 may be equal to each other.

Each of the first to fourth wiring patterns WP1 to WP4 and each of the first and second via patterns VP1 and VP2 may include a second barrier conductive film 222 and a second filling conductive film 224 that are stacked or formed in order. The second barrier conductive film 222 may include a metal or a metal nitride for reducing, limiting, or minimizing the diffusion of the second filling conductive film 224. For example, the second barrier conductive film 222 may include, in some example embodiments, at least one of titanium (Ti), tantalum (Ta), tungsten (W), nickel (Ni), cobalt (Co), platinum (Pt), alloys thereof or nitrides thereof. In some example embodiments, the second barrier conductive film 222 may include at least one of a titanium film (Ti film), a tantalum film (Ta film), a titanium nitride film (TiN film) or a tantalum nitride film (TaN). The second filling conductive film 224 may fill the region or volume of the first to fourth wiring patterns WP1 to WP4 that remains after the second barrier conductive film 222 is formed. For example, the second filling conductive film 224 may include, in some example embodiments, at least one of aluminum (Al), copper (Cu), tungsten (W), molybdenum (Mo), cobalt (Co), ruthenium (Ru) or alloys thereof. In some example embodiments, the second filling conductive film 224 may include copper (Cu).

The second etch stop layer 305 may be formed on the first inter-wiring insulating film 210 and the first to fourth wiring patterns WP1 to WP4. The second etch stop layer 305 may extend (e.g., conformally) along the first inter-wiring insulating film 210 and the first upper pattern UP1 and may contact therewith. The second etch stop layer 305 may not extend along the first lower pattern LP1 and may not contact the first lower pattern LP1. For example, the second etch stop layer 305 may extend along the profile of the upper face of the first Inter-wiring insulating film 210, the side face and upper face of the first upper pattern UP1. The second etch stop layer 305 may not completely fill the region or space between the first to fourth wiring patterns WP1 to WP4. For example, as shown in FIG. 2, a portion of the second etch stop layer 305 that is in contact with the first wiring pattern WP1 may be laterally spaced apart from a portion of the second etch stop layer 305 that is in contact with the second wiring pattern WP2.

In some example embodiments, the second etch stop layer 305 may include a material with relatively lower step coverage characteristics. For example, as shown in FIG. 2, a thickness T1 of the second etch stop layer 305 on the upper surface of the first inter-wiring insulating film 210 and/or a thickness T2 of the second etch stop layer 305 on the side face of the first upper pattern UP1 may be lesser than a thickness T3 of the second etch stop layer 305 on the upper surface of the first upper pattern UP1.

The second etch stop layer 305 may be provided as an etch stop layer in an etching process for forming the upper via pattern UVP. The second etch stop layer 305 may include, for example, in some example embodiments, at least one of silicon nitride (SiN), silicon oxynitride (SiON), silicon oxycarbonitride (SiOCN), silicon boronitride (SiBN), silicon oxyboronitride (SiOBN), silicon oxycarbide (SiOC), silicon carbonitride (SiCN), aluminum nitride (AlN), aluminum oxide (AlO) or a combination thereof.

The second inter-wiring insulating film 310 may be formed on the second etch stop layer 305. The second inter-wiring insulating film 310 may cover the second etch stop layer 305. The second inter-wiring insulating film 310 may fill at least a part of the region or space between the first to fourth wiring patterns WP1 to WP4. For example, as shown in FIG. 2, portions of the second inter-wiring insulating film 310 may be interposed between the portion of the second etch stop layer 305 that is in contact with the first wiring pattern WP1 and the portion of the second etch stop layer 305 that is in contact with the second wiring pattern WP2.

In some example embodiments, the second inter-wiring insulating film 310 may include or otherwise define a first void 310v1. The first void 310v1 may be formed in a relatively narrower region between the first to fourth wiring patterns WP1 to WP4. For example, as shown in FIG. 2, the first void 310v1 may be formed inside the second inter-wiring insulating film 310 between the first wiring pattern WP1 and the second wiring pattern WP2. The first void 310v1 may be, for example, an empty space and/or an air gap. Because the first void 310v1 may have a low dielectric constant compared to an insulating material such as silicon oxide, the performance of the integrated circuit may be improved by reducing the parasitic capacitance between the first to fourth wiring patterns WP1 to WP4.

The second inter-wiring insulating film 310 may include, in some example embodiments, at least one of silicon oxide, silicon nitride, silicon oxynitride, silicon oxycarbide, silicon boron nitride, silicon boron carbonitride, silicon oxycarbonitride, the low dielectric constant material, the ultra-low dielectric constant material, the high dielectric constant material and/or a combination thereof. In some example embodiments, the second inter-wiring insulating film 310 may include the same material as the first inter-wiring insulating film 210. For example, the first inter-wiring insulating film 210 and the second inter-wiring insulating film 310 may have the same material composition. In some example embodiments, the first inter-wiring insulating film 210 and the second inter-wiring insulating film 310 may include the same low dielectric constant material.

The upper wiring patterns UWP may be spaced apart from each other and formed on the second inter-wiring insulating film 310. In some example embodiments, the upper wiring patterns UWP may be formed inside the second inter-wiring insulating film 310, for instance, within trenches defined in the second inter-wiring insulating film 310. The upper wiring patterns UWP may be electrically insulated from each other by the second inter-wiring insulating film 310.

The upper via patterns UVP may be formed between the first to fourth wiring patterns WP1 to WP4 and the upper wiring patterns UWP. Each upper via pattern UVP may extend in the vertical direction from at least a part of the lower face of the upper wiring patterns UWP. The upper via patterns UVP may electrically connect any of the first to fourth wiring patterns WP1 to WP4 and the upper wiring patterns UWP. For example, and as illustrated, one of the upper via patterns UVP may penetrate the second inter-wiring insulating film 310 and the second etch stop layer 305, and may be connected to the first upper pattern UP1 of the first wiring pattern WP1. Also, for example, another upper via patterns UVP may penetrate the second inter-wiring insulating film 310 and the second etch stop layer 305, and may be connected to the first upper pattern UP1 of the third wiring pattern WP3.

In some example embodiments, the side faces of the upper via patterns UVP may be continuous or collinear with the side faces of the upper wiring patterns UWP. For example, as shown, the side faces of the upper via patterns UVP may be uninterruptedly or smoothly connected to the side faces of the upper wiring patterns UWP.

Each upper wiring pattern UWP and each upper via pattern UVP may include a third barrier conductive film 322 and a third filling conductive film 324 that are stacked or formed in order. The third barrier conductive film 322 may include a metal or a metal nitride for reducing, limiting, or minimizing the diffusion of the third filling conductive film 324. For example, the third barrier conductive film 322 may include, in some example embodiments, at least one of titanium (Ti), tantalum (Ta), tungsten (W), nickel (Ni), cobalt (Co), platinum (Pt), an alloy thereof, or a nitride thereof. In some example embodiments, the third barrier conductive film 322 may include at least one of a titanium film (Ti film), a tantalum film (Ta film), a titanium nitride film (TiN film), or a tantalum nitride film (TaN). The third filling conductive film 324 may fill the region or volume of the upper wiring patterns UWP that remains after the third barrier conductive film 322 is formed. For example, the third filling conductive film 324 may include, in some example embodiments, at least one of aluminum (Al), copper (Cu), tungsten (W), molybdenum (Mo), cobalt (Co), ruthenium (Ru) or alloys thereof. In some example embodiments, the third filling conductive film 324 may include copper (Cu).

The upper inter-wiring insulating film 410 may be formed on the third etch stop layer 405 and the upper wiring patterns UWP. For example, the third etch stop layer 405 may conformally extend along the upper surface of the second inter-wiring insulating film 310 and the upper surfaces of the upper wiring patterns UWP. The third etch stop layer 405 may include, in some example embodiments, at least one of silicon nitride (SiN), silicon oxynitride (SiON), silicon oxycarbonitride (SiOCN), silicon boronitride (SiBN), silicon oxyboronitride (SiOBN), silicon oxycarbide (SiOC), silicon carbonitride (SiCN), aluminum nitride (AlN), aluminum oxide (AlO) or a combination thereof.

The upper inter-wiring insulating film 410 may be formed on the third etch stop layer 405. The upper inter-wiring insulating film 410 may cover the upper surface of the third etch stop layer 405. The upper inter-wiring insulating film 410 may include, in some example embodiments, at least one of silicon oxide, silicon nitride, silicon oxynitride, silicon oxycarbide, silicon boron nitride, silicon boron carbonitride, silicon oxycarbonitride, the low dielectric constant material, the ultra-low dielectric constant material, the high dielectric constant material, and/or combinations thereof.

As integrated circuits are progressively miniaturized, the wiring structures included in the integrated circuit are also miniaturized. It is desirable to improve the performance and/or reliability of the integrated circuit by reducing, limiting, or minimizing damage to the wiring structure, and limiting an increase in resistance value of the wiring structure and limiting an increase in leakage current in the wiring structure.

In the integrated circuit, according to some example embodiments, the second etch stop layer 305 may improve the performance and/or reliability of the integrated circuit, by inducing formation of a first void 310v1 between the first to fourth wiring patterns WP1 to WP4. For example, as discussed above, the second etch stop layer 305 may extend along the side face and upper surface of the first upper pattern UP1 of each of the first to fourth wiring patterns WP1 to WP4, and may include a material with a relatively lower step coverage characteristics. As discussed above, the external angle (e.g., 02 of FIGS. 3 and 4) formed by the side face of the first upper pattern UP1 with respect to the horizontal plane may be an acute angle. Accordingly, the first void 310v1 may be effectively formed inside the relatively narrower region or space between the first to fourth wiring patterns WP1 to WP4 in the process of forming the second inter-wiring insulating film 310.

Also, as discussed above, the second etch stop layer 305 may extend along the upper surface of the first upper pattern UP1, and the upper surface of the first inter-wiring insulating film 210 and the side faces of the first upper pattern UP1 between adjacent wiring patterns (e.g., the first wiring pattern WP1 and the second wiring pattern WP2). The second etch stop layer 305 may improve or maximize the movement path of metal atoms (e.g., copper (Cu)), compared to a structure in which only an inter-wiring insulating film is interposed between the adjacent wiring patterns (e.g., the lower inter-wiring insulating film 110 and the lower wiring patterns LWP). As a result, an electromigration phenomenon between the first to fourth wiring patterns WP1 to WP4 may be reduced, thereby providing an integrated circuit with improved performance and/or reliability.

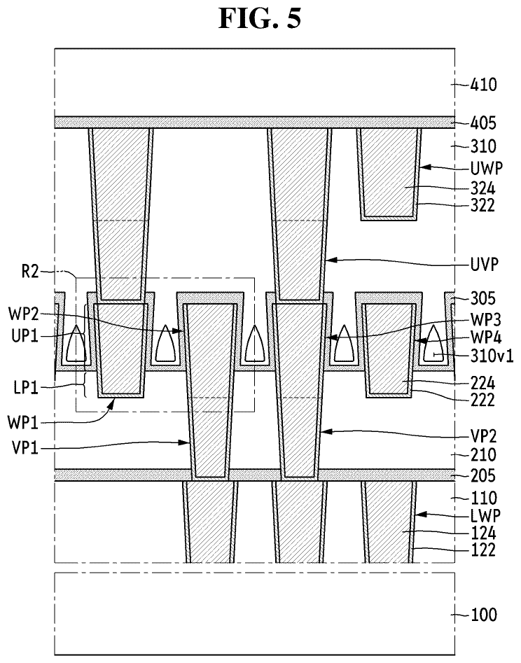

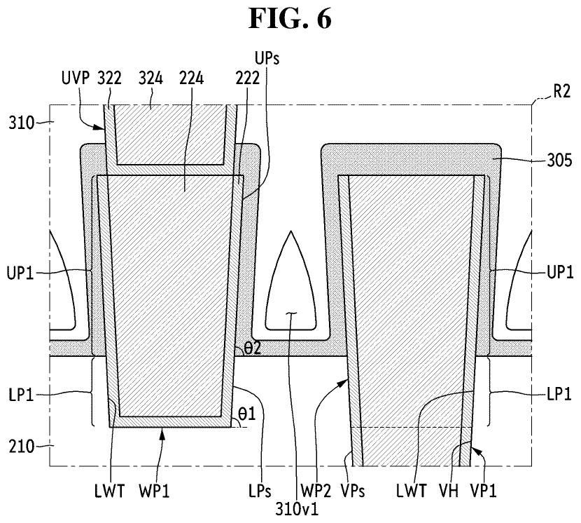

FIG. 5 is a schematic cross-sectional view of an integrated circuit, according to some example embodiments. FIG. 6 is an enlarged view of a region R2 of FIG. 5. The integrated circuit in FIGS. 5 and 6 may be same as or similar in some respects to the integrated circuit of FIGS. 1-4, and therefore may be best understood with reference thereto where like numerals indicate like elements not described again in detail.

Referring to FIGS. 5 and 6, in the integrated circuit, according to some example embodiments, the side face LPs of the first lower pattern LP1 and the side faces UPs of the first upper pattern UP1 may be continuous or collinear.

For example, the side face UPs of the first upper pattern UP1 may be smoothly or uninterruptedly connected to the side face LPs of the first lower pattern LP1. For example, as shown in FIG. 6, at the interface between the first lower pattern LP1 and the first upper pattern UP1 (or the upper surface of the first inter-wiring insulating film 210), the width of the first lower pattern LP1 and the width of the first upper pattern UP1 may be equal to each other.

In FIG. 6, although the first external angle θ1 formed by the side face LPs of the first lower pattern LP1 and the second external angle θ2 formed by the side face UPs of the first upper pattern UP1 are shown as being equal to each other, this is merely an example. As discussed above with reference to FIGS. 3 and 4, the first external angle θ1 and the second external angle θ2 in FIG. 6 may be different from each other.

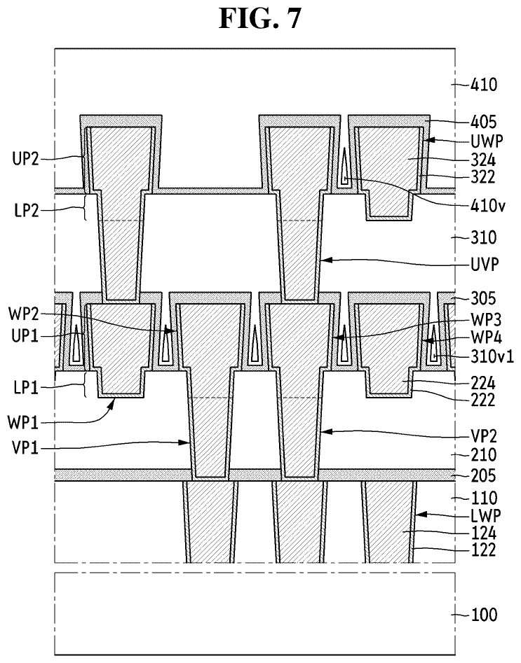

FIGS. 7 to 9 are various schematic cross-sectional views of an integrated circuit, according to some example embodiments. The integrated circuit in FIGS. 7-9 may be same as or similar in some respects to the integrated circuits of FIGS. 1-6, and therefore may be best understood with reference thereto where like numerals indicate like elements not described again in detail.

Referring to FIG. 7, in the integrated circuit, according to some example embodiments, each upper wiring pattern UWP may include a second lower pattern LP2 and a second upper pattern UP2 that are defined on the basis of the upper surface of the second inter-wiring insulating film 310.

The second lower pattern LP2 may be located within the second inter-wiring insulating film 310. The second upper pattern UP2 may be located on the upper surface of the second inter-wiring insulating film 310 and may be connected to the upper portions of the second lower pattern LP2. The second lower pattern LP2 may be same as or similar to the first lower pattern LP1 in some respects, and the second upper pattern UP2 may be same as or similar to the first upper pattern UP1 in some respects, and detailed descriptions thereof are omitted for the sake of brevity.

The third etch stop layer 405 may extend along the second inter-wiring insulating film 310 and the second upper pattern UP2. For example, the second etch stop layer 305 may extend along the profile of the upper surface of the second inter-wiring insulating film 310 and the side face and upper surface of the second upper pattern UP2. The third etch stop layer 405 may not completely fill the region or space between the upper wiring patterns UWP. The third etch stop layer 405 may be same as or similar to the second etch stop layer 305, and therefore, the detailed description thereof is omitted for the sake of brevity.

In some example embodiments, the upper inter-wiring insulating film 410 may include or define a second void 410v. The second void 410v may be formed inside a relatively narrower region between the upper wiring patterns UWP. The second void 410v may be same as or similar to the first void 310v1, and therefore, the detailed explanation description thereof is omitted for the sake of brevity.

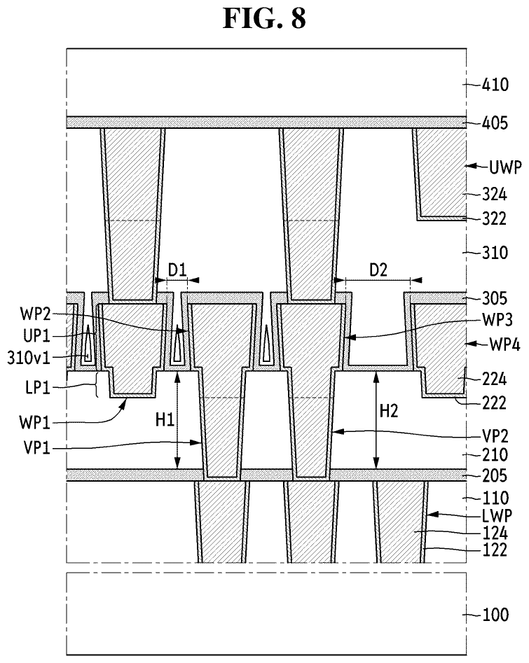

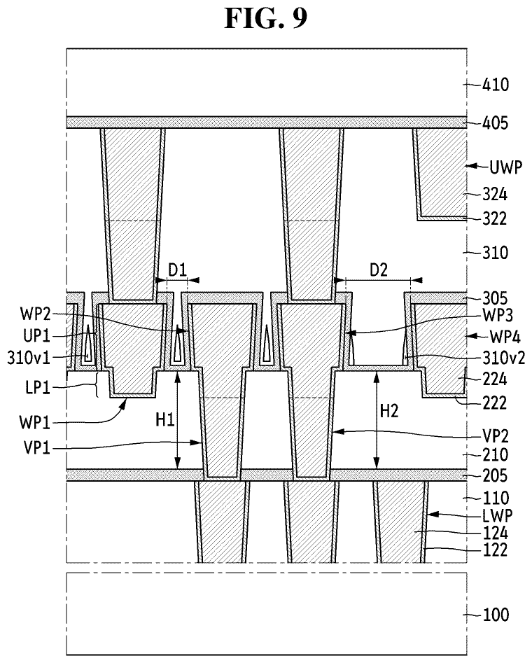

Referring to FIGS. 8 and 9, in the integrated circuit, according to some example embodiments, the third wiring pattern WP3 and the fourth wiring pattern WP4 may be spaced apart from each other by a relatively wide gap.

For example, the first wiring pattern WP1 and the second wiring pattern WP2 adjacent to each other may be spaced apart by a first distance D1, and the third wiring pattern WP3 and the fourth wiring pattern WP4 adjacent to each other may be spaced apart by a second distance D2 greater than the first distance D1. The first void 310v1 may be formed or defined in the relatively narrower region between the first wiring pattern WP1 and the second wiring pattern WP2. A void may be absent in the relatively wider region between the third wiring pattern WP3 and the fourth wiring pattern WP4.

In some example embodiments, the height of the first inter-wiring insulating film 210 between the third wiring pattern WP3 and the fourth wiring pattern WP4 may be equal to the height of the first inter-wiring insulating film 210 between the first wiring pattern WP1 and the second wiring pattern WP2. For example, the height H1 of the upper surface of the first inter-wiring insulating film 210 between the first wiring pattern WP1 and the second wiring pattern WP2 may be equal to the height H2 of the upper surface of the first inter-wiring insulating film 210 between the third wiring pattern WP3 and the fourth wiring pattern WP4, measured from the upper surface of the first etch stop layer 205.

Referring to FIG. 9, in the integrated circuit, according to some example embodiments, a third void 310v2 may be formed or defined between the second etch stop layer 305 and the second inter-wiring insulating film 310.

The third void 310v2 may be formed or defined in the relatively wider region between the third wiring pattern WP3 and the fourth wiring pattern WP4. The third void 310v2 may be an empty volume or an air gap surrounded by the second etch stop layer 305 and the second inter-wiring insulating film 310. As discussed above, since the external angle (e.g., 02 of FIGS. 3 and 4) formed by the side face of the first upper pattern UP1 with respect to the horizontal plane may be an acute angle, the inclination of the second etch stop layer 305 may cause the formation of the third void 310v2 in the process of forming the second inter-wiring insulating film 310.

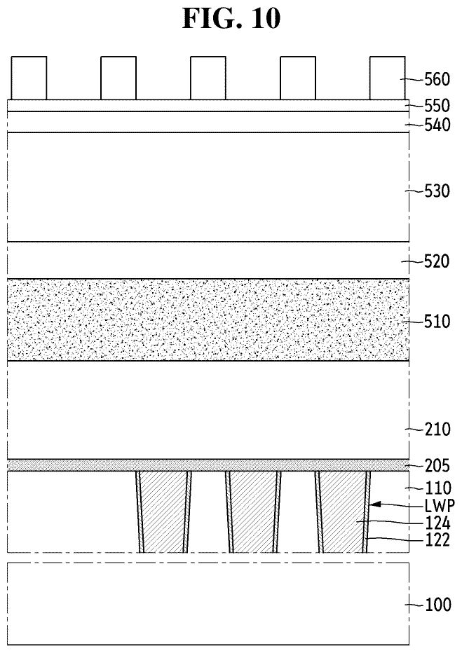

FIGS. 10 to 23 are operations in a method for fabricating an integrated circuit, according to some example embodiments. For sake of brevity, the operations may be best understood with reference to FIGS. 1 to 9 and like numerals indicate like elements not described again in detail. It is understood that additional operations can be provided before, during, and after the operations in FIGS. 10 to 23, and some of the operations described below can be replaced or eliminated, for additional embodiments of the method. The order of the operations/processes may be interchangeable, or two or more operations can be performed simultaneously.

Referring to FIG. 10, a first etch stop layer 205, a first inter-wiring insulating film 210, first to fourth hardmask films 510, 520, 530 and 540, a first anti-reflection film 550, and a first photoresist pattern 560 are sequentially formed on the lower inter-wiring insulating film 110 and the lower wiring pattern LWP.

The first to fourth hardmask films 510, 520, 530 and 540 may each include a material having an etching selectivity with respect to the first inter-wiring insulating film 210. For example, the first to fourth hardmask films 510, 520, 530 and 540 may each independently include, in some example embodiments, at least one of a silicon-based hardmask such as silicon oxide (SiO), silicon nitride (SiN), silicon oxynitride (SiON) or amorphous silicon; a metal-based hardmask such as titanium nitride (TiN), tungsten (W), aluminum oxide (AIO) or WDC (W (tungsten) doped carbon); a carbon-based hardmask such as an ACL (amorphous carbon layer) or a DLC (diamond-like carbon); SOH (spin-on hardmask); or combinations thereof.

As an example, the first hardmask film 510 may include at least one of a metal-based hardmask such as a titanium nitride film (TiN film) and/or a carbon-based hardmask such as an ACL. As an example, the second hardmask film 520 may include a silicon oxynitride film (SiON film), the third hardmask film 530 may include SOH, and the fourth hardmask film 540 may include a silicon oxynitride film (SiON film). In some example embodiments, one or more of the second to fourth hardmask films 520, 530, and 540 may be omitted depending on application and/or design.

The first anti-reflection film 550 may be a BARC (bottom anti-reflection coating) formed to reduce or limit light reflection in a photolithography process using the first photoresist pattern 560.

The first photoresist pattern 560 may be a photoresist film patterned by light irradiated in the photolithography process. The first photoresist pattern 560 may be used as an etching mask in an etching process to be described below.

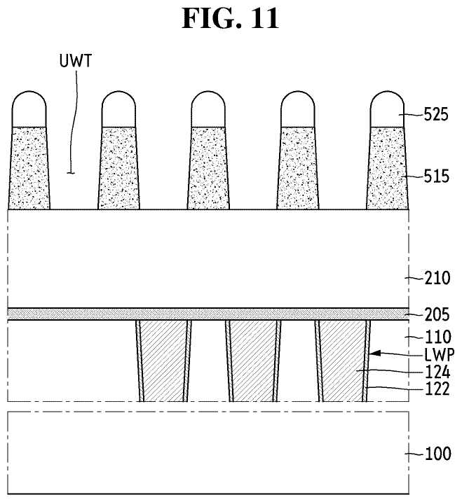

Referring to FIGS. 10 and 11, the first hardmask film 510 is patterned, using the first photoresist pattern 560 as an etching mask.

For example, the patterning process on the first to fourth hardmask films 510, 520, 530, and 540 may be performed, using the first photoresist pattern 560 as an etching mask. Thus, a first hardmask pattern 515 may be formed from the first hardmask film 510. The first hardmask pattern 515 may have a shape same as or similar to the first photoresist pattern 560 that is transferred. The first hardmask pattern 515 may include or define a second wiring trench UWT. The second wiring trench UWT may be formed at a position corresponding to first to fourth wiring patterns WP1 to WP4 to be described below. A side face of the second wiring trench UWT may be defined by the first hardmask pattern 515, and the second wiring trench UWT may expose a part of the upper surface of the first inter-wiring insulating film 210.

In some example embodiments, the patterning process may form a second hardmask pattern 525 hardmask on the first hardmask pattern 515. In FIG. 11, the third hardmask film 530 and the fourth hardmask film 540 are shown as being completely removed, but this is only an example, and in some example embodiments, the patterned third hardmask film 530 and/or the patterned fourth hardmask film 540 may be retained.

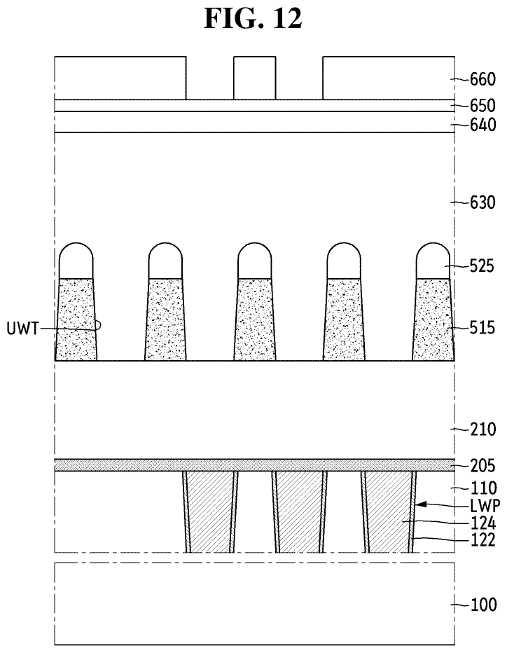

Referring to FIGS. 11 and 12, fifth and sixth hardmask films 630 and 640, a second anti-reflection film 650, and a second photoresist pattern 660 are sequentially formed on the first inter-wiring insulating film 210, the first hardmask pattern 515, and the second hardmask pattern 525.

The fifth and sixth hardmask films 630 and 640 may each include a material having an etching selectivity with respect to the first inter-wiring insulating film 210. For example, the fifth and sixth hardmask films 630 and 640 may each independently include, in some example embodiments, at least one of a silicon-based hardmask such as silicon oxide (SiO), silicon nitride (SiN), silicon oxynitride (SiON) or amorphous silicon; metal-based hardmask such as titanium nitride (TiN), tungsten (W), aluminum oxide (AIO) or WDC (W (tungsten) doped carbon); carbon-based hardmask such as ACL (amorphous carbon layer) or DLC (diamond-like-carbon); SOH (Spin-On Hardmask); or combinations thereof.

As an example, the fifth hardmask film 630 may include SOH. As an example, the sixth hardmask film 640 may include a silicon oxynitride film (SiON film). In some example embodiments, one or more portions of the fifth and sixth hardmask films 630 and 640 may be omitted, depending on application and/or design.

The second anti-reflection film 650 may be a BARC (bottom anti-reflection coating) formed to reduce or limit light reflection in a photolithography process using the second photoresist pattern 660.

The second photoresist pattern 660 may be a photosensitive film patterned by light irradiated in the photolithography process. The second photoresist pattern 660 may be used as an etching mask in an etching process to be described below.

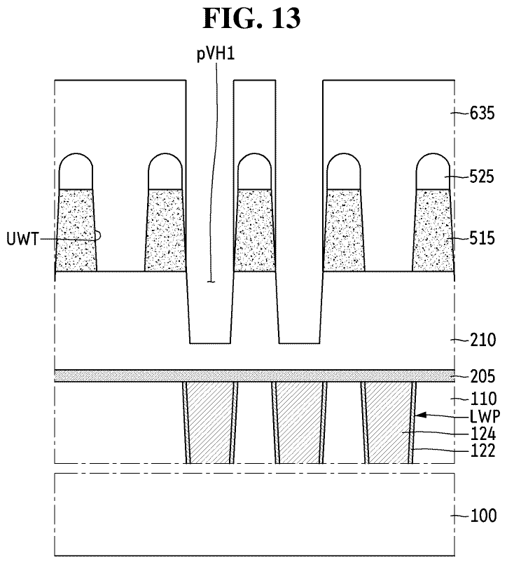

Referring to FIGS. 12 and 13, the first inter-wiring insulating film 210 may be patterned, using the second photoresist pattern 660 as an etching mask.

For example, a patterning process may be performed on the fifth and sixth hardmask films 630 and 640, using the second photoresist pattern 660 as an etching mask. Thus, a third hardmask pattern 635 may be formed from the fifth hardmask film 630. The third hardmask pattern 635 may have a form same as or similar to the second photoresist pattern 660 that may be transferred. In FIG. 13, the sixth hardmask film 640 is shown as being completely removed, but this is merely an example, and, in some example embodiments, at least portions of the patterned sixth hardmask film 640 may be retained.

Next, an etching process may be performed on the first inter-wiring insulating film 210, using the third hardmask pattern 635 as an etching mask. As the etching process is performed, a first preliminary via hole pVH1 may be formed in the first inter-wiring insulating film 210. The first preliminary via hole pVH1 may be formed at a position corresponding to a via hole VH to be described below. A lower face of the first preliminary via hole pVH1 may be spaced apart from the first etch stop layer 205. A depth at which the first preliminary via hole pVH1 is formed may be smaller than the thickness of the first inter-wiring insulating film 210.

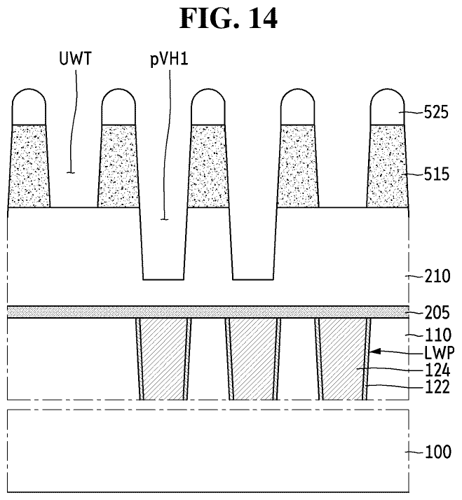

Referring to FIGS. 13 and 14, the third hardmask pattern 635 is removed.

As the third hardmask pattern 635 is removed, the second wiring trench UWT and the first preliminary via hole pVH1 may expose portions of the upper surface of the first inter-wiring insulating film 210.

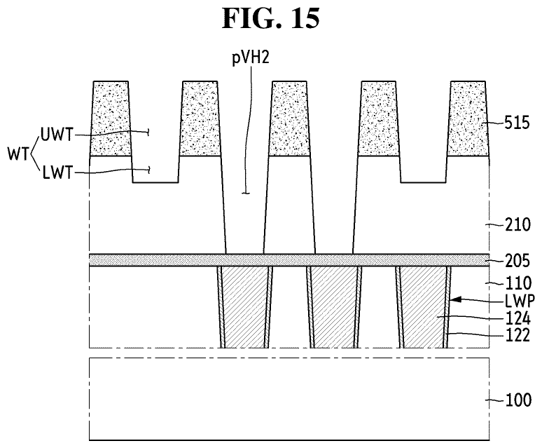

Referring to FIGS. 14 and 15, the first inter-wiring insulating film 210 is patterned, using the first hardmask pattern 515 as an etching mask.

For example, an etching process may be performed on the region of the first inter-wiring insulating film 210 exposed by the second wiring trench UWT and the first preliminary via hole pVH1. As the etching process is performed, a first wiring trench LWT may be formed under the second wiring trench UWT. The first wiring trench LWT and the second wiring trench UWT may form wiring trenches WT corresponding to first to fourth wiring patterns WP1 to WP4 to be described below.

As the etching process is performed, a second preliminary via hole pVH2 may be formed from the first preliminary via hole pVH1. The second preliminary via hole pVH2 may penetrate the first inter-wiring insulating film 210 to expose a part of the upper surface of the first etch stop layer 205. The first etch stop layer 205 may be provided as an etch stop layer in the etching process for forming the second preliminary via hole pVH2.

In some example embodiments, the second hardmask pattern 525 may be completely removed in the process of forming the first wiring trench LWT and the second preliminary via hole pVH2.

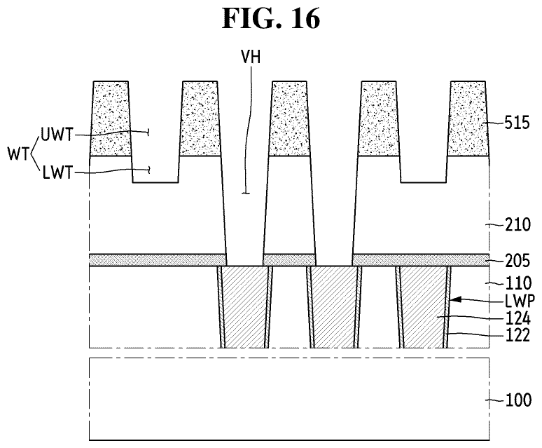

Referring to FIGS. 15 and 16, an etching process may be performed on a region of the first etch stop layer 205 exposed by the second preliminary via hole pVH2. As the etching process is performed, a via hole VH may be formed from the second preliminary via hole pVH2. The via hole VH may penetrate the first etch stop layer 205 to expose a part of the upper surface of the lower wiring pattern LWP.

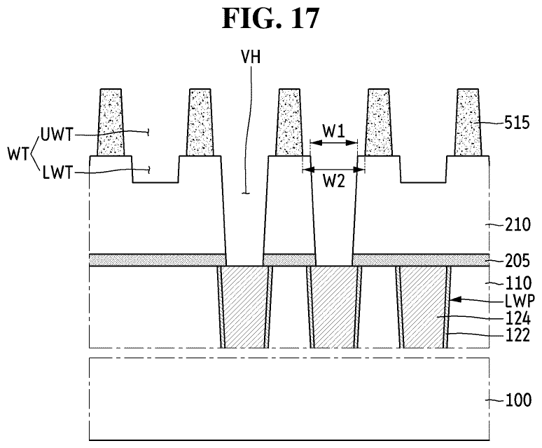

Referring to FIGS. 16 and 17, a trimming process is performed on the first hardmask pattern 515.

As the trimming process is performed, a part of the first hardmask pattern 515 may be removed. For example, at an interface between the first inter-wiring insulating film 210 and the first hardmask pattern 515, the second width W2 of the second wiring trench UWT may be greater than the first width W1 of the first wiring trench LWT. The trimming process may include, in some example embodiments, a stripping process on the first hardmask pattern 515.

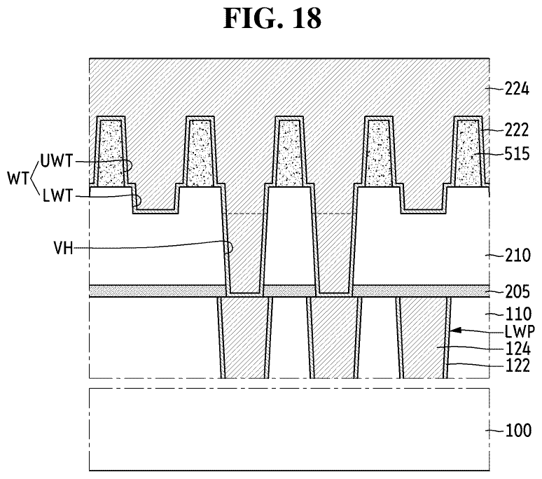

Referring to FIGS. 17 and 18, a second barrier conductive film 222 and a second filling conductive film 224 are sequentially formed in the wiring trench WT and the via hole VH.

The second barrier conductive film 222 may include a metal or a metal nitride for reducing, limiting, or minimizing diffusion of the second filling conductive film 224. The second filling conductive film 224 may fill the region of the wiring trench WT and the region of the via hole VH that remain after the second barrier conductive film 222 is formed.

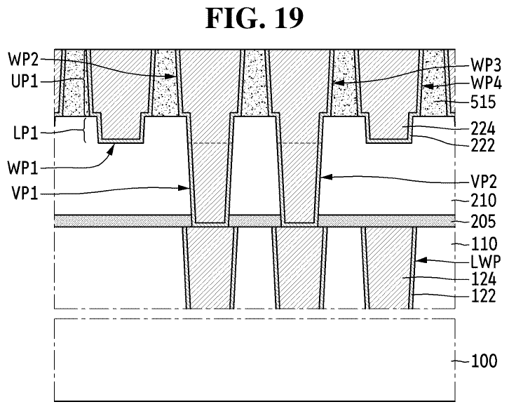

Referring to FIGS. 18 and 19, a planarization process is performed on the second barrier conductive film 222 and the second filling conductive film 224.

As the planarization process is performed, the upper surface of the first hardmask pattern 515 may be exposed. As a result, the first to fourth wiring patterns WP1 to WP4 and the first and second via patterns VP1 and VP2 separated from each other by the first inter-wiring insulating film 210 and the first hardmask pattern 515 may be formed. In addition, each of the first to fourth wiring patterns WP1 to WP4 may include a first lower pattern LP1 and a first upper pattern UP1 that may be defined based on the upper surface of the first inter-wiring insulating film 210. The planarization process may include, in some example embodiments, a chemical mechanical polishing (CMP) process.

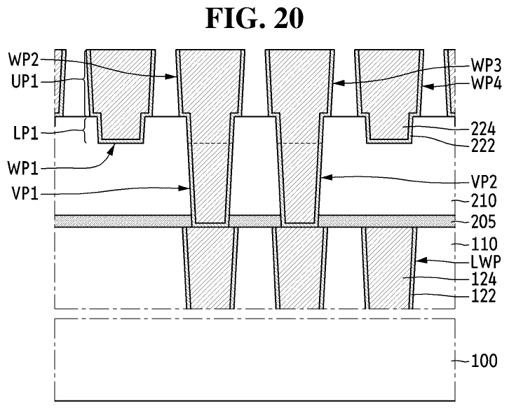

Referring to FIGS. 19 and 20, the first hardmask pattern 515 is removed.

As the first hardmask pattern 515 is removed, the upper surface of the first inter-wiring insulating film 210 and the side face of the first upper pattern UP1 may be exposed.

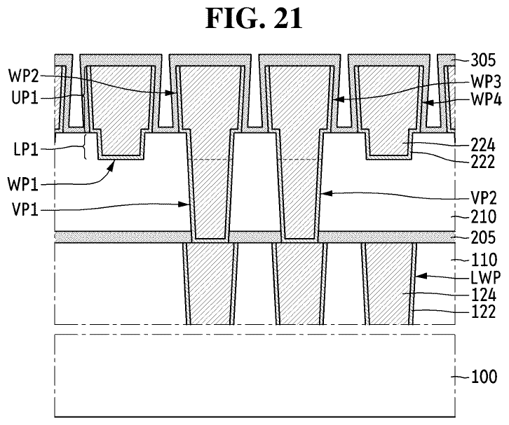

Referring to FIGS. 20 and 21, a second etch stop layer 305 is formed (e.g., conformally) on the first inter-wiring insulating film 210 and the first to fourth wiring patterns WP1 to WP4.

The second etch stop layer 305 may extend along the profile of the upper surface of the first inter-wiring insulating film 210 and the side face and upper surface of the first upper pattern UP1. The second etch stop layer 305 may not completely fill the region or space between the first to fourth wiring patterns WP1 to WP4.

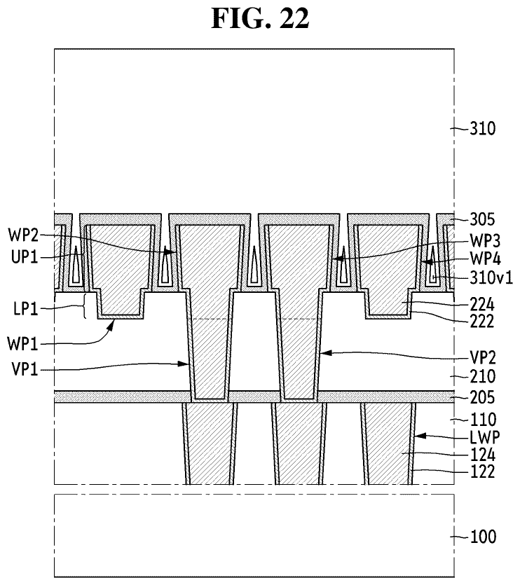

Referring to FIGS. 21 and 22, a second inter-wiring insulating film 310 is formed on the second etch stop layer 305.

The second etch stop layer 305 may be covered by the second inter-wiring insulating film 310. The second inter-wiring insulating film 310 may fill at least a part of the regions between the first to fourth wiring patterns WP1 to WP4. In some example embodiments, the second inter-wiring insulating film 310 may include a first void 310v1 formed inside a relatively narrower region between the first to fourth wiring patterns WP1 to WP4.

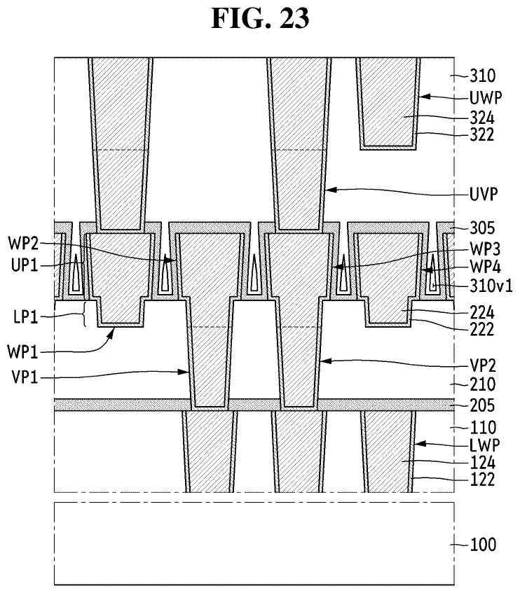

Referring to FIGS. 22 and 23, upper wiring patterns UWP and upper via patterns UVP are formed on the second inter-wiring insulating film 310.

For example, the upper wiring patterns UWP may be formed in the second inter-wiring insulating film 310. The upper via patterns UVP may penetrate the second inter-wiring insulating film 310 and the second etch stop layer 305 to connect the first to fourth wiring patterns WP1 to WP4 and the upper wiring pattern UWP.

Referring briefly to FIG. 1, a third etch stop layer 405 is formed on the second inter-wiring insulating film 310 and the upper wiring patterns UWP. The integrated circuit discussed with reference to FIGS. 1 to 4 may be fabricated, accordingly.

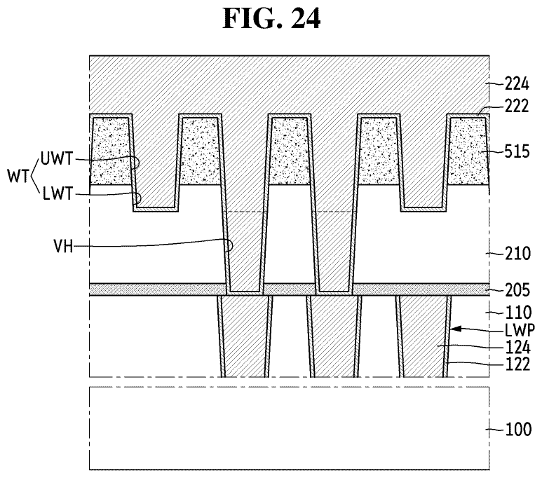

FIG. 24 is an operation in a method for fabricating the integrated circuit according to some example embodiments. For sake of brevity of explanation, operations related to FIGS. 1 to 23 will not be described in detail and may be best understood with reference thereto. In some example embodiments, FIG. 24 may be an intermediate operation that may be performed after operations in FIG. 16.

Referring to FIG. 24, the second barrier conductive film 222 and the second filling conductive film 224 are sequentially formed in the wiring trench WT and the via hole VH.

In some example embodiments, the operations in FIG. 17 may be omitted. The operation of forming the second barrier conductive film 222 and the second filling conductive film 224 may be same as or similar to the operation discussed above with reference to FIG. 18, and therefore, the detailed description thereof is omitted herein. Next, the operations in FIGS. 19 to 23 and FIG. 1 may be performed. The integrated circuit of FIGS. 5 and 6 may be fabricated, accordingly.

While several example embodiments have been provided in the present disclosure, it should be understood that the disclosed systems and methods might be embodied in many other specific forms without departing from the spirit or scope of the present disclosure. The present examples are to be considered as illustrative and not restrictive, and the intention is not to be limited to the details given herein. For example, the various elements or components may be combined or integrated in another system or certain features may be omitted, or not implemented.

In addition, techniques, systems, subsystems, and methods described and illustrated in the various embodiments as discrete or separate may be combined or integrated with other systems, modules, techniques, or methods without departing from the scope of the present disclosure. Other items shown or discussed as coupled or directly coupled or communicating with each other may be indirectly coupled or communicating through some interface, device, or intermediate component whether electrically, mechanically, or otherwise. Other examples of changes, substitutions, and alterations are ascertainable by one skilled in the art and could be made without departing from the spirit and scope disclosed herein.

What is claimed is:

1. An integrated circuit, comprising:
a substrate;
a first inter-wiring insulating film on the substrate;
a first wiring pattern and a second wiring pattern spaced apart from each other on the first inter-wiring insulating film;
a first etch stop layer on the first inter-wiring insulating film, the first wiring pattern, and the second wiring pattern; and
a second inter-wiring insulating film on the first etch stop layer, wherein
each of the first wiring pattern and the second wiring pattern includes a first lower pattern in the first inter-wiring insulating film, and a first upper pattern on an upper surface of the first inter-wiring insulating film,
the first etch stop layer extends along profiles of the upper surface of the first inter-wiring insulating film, and a side face and an upper surface of the first upper pattern, and
the second inter-wiring insulating film defines a first void between the first upper pattern of the first wiring pattern and the first upper pattern of the second wiring pattern.

2. The integrated circuit of claim 1,
wherein a first width of the first lower pattern is less than a second width of the first upper pattern at an interface between the first lower pattern and the first upper pattern.

3. The integrated circuit of claim 1, further comprising:
a lower inter-wiring insulating film between the substrate and the first inter-wiring insulating film;
a lower wiring pattern in the lower inter-wiring insulating film;
a second etch stop layer on an upper surface of the lower inter-wiring insulating film and an upper surface of the lower wiring pattern; and
a via pattern penetrating the first inter-wiring insulating film and the second etch stop layer and connecting the first lower pattern and the lower wiring pattern.

4. The integrated circuit of claim 3,
wherein a width of the first lower pattern and a width of the via pattern are equal to each other at an interface between the first lower pattern and the via pattern.

5. The integrated circuit of claim 1, further comprising:
an upper wiring pattern on the second inter-wiring insulating film; and
an upper via pattern penetrating the second inter-wiring insulating film and the first etch stop layer and connecting the first upper pattern and the upper wiring pattern.

6. The integrated circuit of claim 5, further comprising:
a second etch stop layer on the second inter-wiring insulating film and the upper wiring pattern, wherein
the upper wiring pattern includes a second lower pattern in the second inter-wiring insulating film, and a second upper pattern on an upper surface of the second inter-wiring insulating film, and
the second etch stop layer extends along profiles of the upper surface of the second inter-wiring insulating film, and a side face and an upper surface of the second upper pattern.

7. The integrated circuit of claim 1,
wherein a thickness of the first etch stop layer on the upper surface of the first upper pattern is greater than a thickness of the first etch stop layer on the upper surface of the first inter-wiring insulating film and a thickness of the first etch stop layer on the side face of the first upper pattern.

8. The integrated circuit of claim 1, further comprising:
a third wiring pattern spaced apart from the second wiring pattern on the first inter-wiring insulating film, wherein
the second wiring pattern is disposed between the first wiring pattern and the third wiring pattern,
a first distance between the first wiring pattern and the second wiring pattern is less than a second distance between the second wiring pattern and the third wiring pattern, and
a height of the upper surface of the first inter-wiring insulating film between the first wiring pattern and the second wiring pattern is equal to a height of the upper surface of the first inter-wiring insulating film between the second wiring pattern and the third wiring pattern.

9. The integrated circuit of claim 8, further comprising:
a second void between the first etch stop layer and the second inter-wiring insulating film and between the second wiring pattern and the third wiring pattern.

10. The integrated circuit of claim 1,
wherein the first inter-wiring insulating film and the second inter-wiring insulating film each include a low dielectric constant material having a dielectric constant that is less than a dielectric constant of silicon oxide.

11. The integrated circuit of claim 10,
wherein the first inter-wiring insulating film and the second inter-wiring insulating film have a same material composition.

12. An integrated circuit, comprising:
a substrate;
a first inter-wiring insulating film on the substrate;
a wiring pattern including a lower pattern in the first inter-wiring insulating film, and an upper pattern on an upper surface of the first inter-wiring insulating film;
an etch stop layer on the first inter-wiring insulating film and the upper pattern; and
a second inter-wiring insulating film on the etch stop layer, wherein
at an interface between the lower pattern and the upper pattern, a first width of the lower pattern is less than a second width of the upper pattern,
the etch stop layer extends along profiles of the upper surface of the first inter-wiring insulating film, and a side face and an upper surface of the upper pattern, and
the second inter-wiring insulating film fills at least a portion of a region on the side face of the upper pattern.

13. The integrated circuit of claim 12,
wherein the second inter-wiring insulating film defines a void on the side face of the upper pattern.

14. The integrated circuit of claim 12, further including:
a void between the etch stop layer and the second inter-wiring insulating film.

15. The integrated circuit of claim 12,
wherein a first external angle formed by the side face of the lower pattern with respect to a horizontal plane parallel to the upper surface of the substrate and a second external angle formed by the side face of the upper pattern with respect to the horizontal plane are different from each other.

16. The integrated circuit of claim 12, further comprising:
a via pattern extending from a lower face of the lower pattern in a vertical direction intersecting the upper surface of the substrate, and penetrating the first inter-wiring insulating film.

17. The integrated circuit of claim 16,
wherein a width of the lower pattern and a width of the via pattern are equal to each other at an interface between the lower pattern and the via pattern.

18. An integrated circuit, comprising:
a substrate;
a lower inter-wiring insulating film on the substrate;
a lower wiring pattern on the lower inter-wiring insulating film;
a first etch stop layer which extends along an upper surface of the lower inter-wiring insulating film and an upper surface of the lower wiring pattern;
a first inter-wiring insulating film on the first etch stop layer;
a wiring pattern including a lower pattern having a first width in the first inter-wiring insulating film, and an upper pattern having a second width on an upper surface of the first inter-wiring insulating film, the second width being greater than the first width;
a via pattern penetrating the first inter-wiring insulating film and the first etch stop layer and connecting the lower pattern and the lower wiring pattern;
a second etch stop layer extending along profiles of an upper surface of the first inter-wiring insulating film, and a side face and an upper surface of the upper pattern; and
a second inter-wiring insulating film on the second etch stop layer,
wherein the second inter-wiring insulating film defines a void on the side face of the upper pattern.

19. The integrated circuit of claim 18, further comprising:
an upper wiring pattern on the second inter-wiring insulating film; and
an upper via pattern penetrating the second inter-wiring insulating film and the second etch stop layer and connecting the upper pattern and the upper wiring pattern.

20. The integrated circuit of claim 18,
wherein a thickness of the second etch stop layer on the upper surface of the upper pattern is greater than a thickness of the second etch stop layer on the upper surface of the first inter-wiring insulating film and a thickness of the second etch stop layer on the side face of the upper pattern.
